(19) United States
(12) Patent Application Publication
(10) Pub. No.: US 2025/0125884 A1
(43) Pub. Date: Apr. 17, 2025

(54) OPTICAL FILM BASED BATTERY MANAGEMENT SYSTEM COMMUNICATION METHOD

(71) Applicant: Vitesco Technologies USA, LLC, Auburn Hills, MI (US)

(72) Inventor: Yong Jiang

(73) Assignee: Vitesco Technologies USA, LLC, Auburn HIlls, MI (US)

(21) Appl. No.: 18/484,785

(22) Filed: Oct. 11, 2023

(51) Int. Cl. H04B 10/80; H04Q 9/00

(52) U.S. Cl. CPC H04B 10/801; H04Q 9/00; H04Q 2209/40

(57) ABSTRACT

A battery management system having at least one optical pathway including a plurality of optical communication devices connected to one of a plurality of batteries. Each optical communication device emits optical signals, the optical signals include data about the batteries. Each of the optical communication devices includes an optical emitter operable for emitting the optical signals, an optical sensor operable for receiving the optical signals, a controlling circuit for processing the optical signals, and a printed circuit board (PCB). The optical emitter, the optical sensor, and the controlling circuit are mounted to the PCB. The optical pathway includes a layer of transparent film, and a layer of reflective film is connected to the layer of transparent film. The optical signals which pass through the layer of transparent film and reflect off of the layer of reflective film are received by the optical sensor of one of the optical communication devices.

### FIELD OF THE INVENTION

The invention relates generally to a battery management system which includes at least one optical pathway for providing communication between multiple batteries in a battery pack.

### BACKGROUND OF THE INVENTION

Current battery management systems (BMS) using wires are bulky and/or expensive, slow, and typically are unable to transmit various data simultaneously. Typical BMS are also vulnerable to cyber-attacks and electromagnetic capability (EMC) interference. Additionally, because current BMS are bulky and include the use of wires, these systems are not always able to meet various packaging requirements.

Accordingly, there exists a need for a BMS which is not subject to cyber-attacks or EMC interference, facilitates desirable data collection and communication, and may be manufactured at a desirable cost.

### SUMMARY OF THE INVENTION

The present invention is a battery management system (BMS) which uses an optical path, instead of an RF path, and is immutable to RF related signal leakage and EMI. The BMS of the present invention also facilitates faster data collection and transition, immutable to cyber-attacks and EMI.

The BMS of the present invention archives fast data collection and communication, is immune to cyber-attacks and EMI, and has an optimal overall cost.

In an embodiment, the present invention is a BMS, having at least one optical pathway including at least one optical communication device connected to one of a plurality of batteries. The optical communication device emits one or more optical signals, the optical signals include data about at least one of the batteries.

In an embodiment, the optical communication device includes a plurality of optical communication devices, where each of the optical communication devices is connected to a corresponding one of the batteries.

In an embodiment, each of the optical communication devices includes an optical emitter operable for emitting the optical signals, an optical sensor operable for receiving the optical signals, a controlling circuit operable for processing the optical signals, and a printed circuit board (PCB). The optical emitter, the optical sensor, and the controlling circuit are mounted to the PCB.

In an embodiment, the optical pathway includes at least one layer of transparent film, a portion of layer of transparent film is mounted to an external surface of a first of the plurality of batteries, and a second portion of the layer of transparent film is mounted to an external surface of a second of the plurality of batteries. At least one layer of reflective film is connected to the layer of transparent film. The optical emitter of each of the plurality of optical communication devices emits the optical signals which pass through the layer of transparent film and reflects off of the layer of reflective film, such that the optical signals emitted by the optical emitter of each of the optical communication devices is received by the optical sensor of one of the optical communication devices.

In an embodiment, the optical pathway includes at least one aperture integrally formed as part of the layer of reflective film. The optical signals pass through the aperture, such that the optical signals are transmitted to a second optical communication device.

In an embodiment, the BMS of the present invention includes a plurality of optical pathways and a plurality of optical communication devices, each of the optical communication devices being part of a corresponding one of the optical pathways, each of the optical pathways connected to and circumscribing a corresponding one of the batteries.

In an embodiment, each of the optical pathways includes a layer of transparent film circumscribing one of the plurality of batteries, and a layer of reflective film connected to the layer of transparent film. In an embodiment, the optical communication device emits at least one the optical signals and receives another of the optical signals.

In an embodiment, each of the optical communication devices includes an optical emitter operable for emitting the optical signals such that the optical signals pass through the layer of transparent film, an optical sensor operable for receiving the optical signals, a PCB, the optical emitter and the optical sensor each mounted to the PCB.

In an embodiment, each of the optical communication devices includes a first band pass filter mounted to the optical emitter, and a second band pass filter mounted to the optical sensor. The first band pass filter restricts the one or more optical signals emitted from the optical emitter and the second band pass filter restricts the one or more optical signals received by the optical sensor to a specific spectrum optical signal, respectively.

In an embodiment, at least one aperture is integrally formed as part of the layer of reflective film, and the specific spectrum optical signal passes through the aperture of a first of the optical pathways and is transferred to a second of the optical pathways.

In an embodiment, the batteries are one of a horizontal battery pack or a vertical battery pack.

In an embodiment, the batteries are configured as a first irregular battery pack and a second irregular battery pack. An extended optical pathway provides communication between the first irregular battery pack and the second irregular battery pack.

In an embodiment, the extended optical pathway includes a layer of transparent film, and a layer of reflective film connected to the layer of transparent film. A first portion of the layer of transparent film is mounted to an external surface of a battery which is part of the first irregular battery pack, and a second portion of the layer of transparent film is mounted to an external surface of a battery which is part of the second irregular battery pack.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1 is a perspective view of a battery having several components of a battery management system, according to embodiments of the present invention;

FIG. 2 is a perspective view of two batteries having several components of a battery management system, according to embodiments of the present invention;

FIG. 3 is a perspective view of two batteries having a battery management system, according to embodiments of the present invention;

FIG. 4 is an exploded view of a battery management system, according to embodiments of the present invention;

FIG. 5 is a perspective view of a battery having an alternate embodiment of a battery management system, according to embodiments of the present invention;

FIG. 6 is a partial exploded view of a battery and an alternate embodiment of a battery management system, according to embodiments of the present invention;

FIG. 7 is perspective view of an alternate embodiment of battery management system, according to embodiments of the present invention;

FIG. 8 is an exploded view of a section of part of an optical pathway used as part of an alternate embodiment of battery management system, according to embodiments of the present invention;

FIG. 9 is a perspective view of a battery pack in a first configuration, where the battery pack is used with an alternate embodiment of a battery management system, according to embodiments of the present invention;

FIG. 10 is a first exploded view of a battery pack in a first configuration, where the battery pack is used with an alternate embodiment of a battery management system, according to embodiments of the present invention;

FIG. 11 is a second exploded view of a battery pack in a first configuration, where the battery pack is used with an alternate embodiment of a battery management system, according to embodiments of the present invention;

FIG. 12 is a perspective view of a battery pack in a second configuration, where the battery pack is used with an alternate embodiment of a battery management system, according to embodiments of the present invention;

FIG. 13 is a perspective view of a battery pack in a third configuration, where the battery pack is used with an alternate embodiment of a battery management system, according to embodiments of the present invention

FIG. 14 is a perspective view of two irregularly shaped battery packs having an alternate embodiment of a battery management system, according to embodiments of the present invention; and

FIG. 15 is an exploded view of an extended optical pathway used as part of an alternate embodiment of a battery management system, according to embodiments of the present invention; and

FIG. 16 is a perspective view of an optical communication device, which is part of an alternate embodiment of a battery management system, according to embodiments of the present invention.

### DETAILED DESCRIPTION OF THE PREFERRED EMBODIMENTS

The following description of the preferred embodiment(s) is merely exemplary in nature and is in no way intended to limit the invention, its application, or uses.

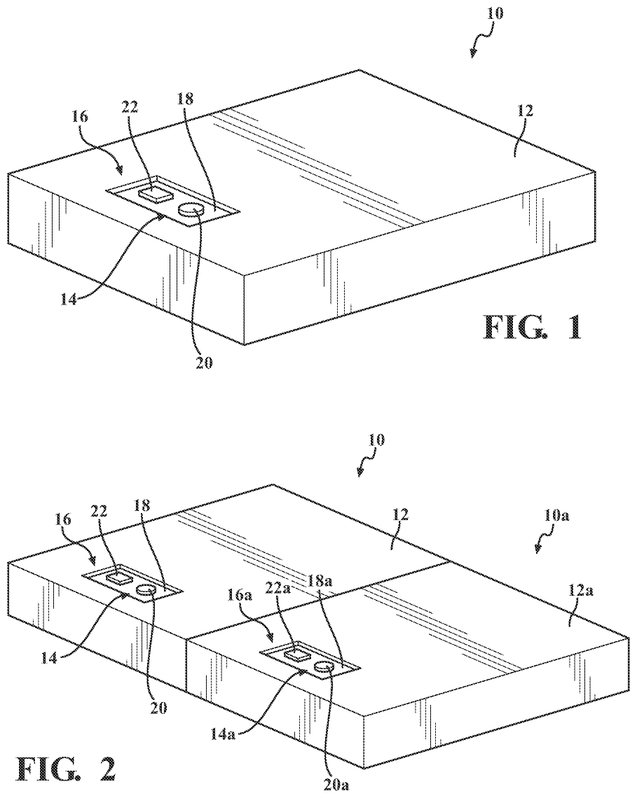

A battery having various components which are part of a battery management system (BMS) according to the present invention is shown in FIG. 1, generally at 10. Referring generally to FIGS. 1-4, the battery 10 includes a housing 12, and integrally formed as part of the housing 12 is an opening, shown generally at 14. Exposed in the opening is an optical communication device, shown generally at 16. The optical communication device 16 includes a printed circuit board (PCB) 18. Mounted to the PCB 18 is an optical emitter 20, an optical sensor 22, and a controlling circuit 36.

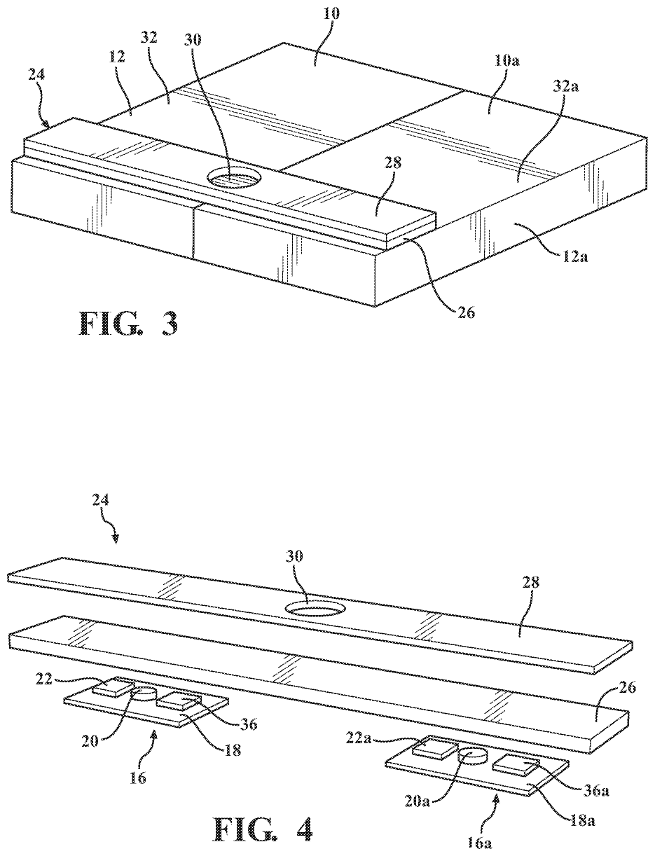

The optical communication device 16 is part of an optical pathway, shown generally at 24, where the optical pathway 24 provides data communication between additional optical communication devices which are part of other batteries. As shown in FIGS. 2 and 3, an additional battery 10a is shown adjacent the battery 10, and each battery 10,10a has an optical communication device 16,16a which is part of the optical pathway 24. The optical communication device 16a is similar to the optical communication device 16, and includes an optical emitter 20a, an optical sensor 22a, and a controlling circuit 36a mounted to a PCB 18a. The optical pathway 24 may have several additional optical communication devices 16,16a, depending upon how many batteries are used.

Referring now to FIGS. 3 and 4, the optical pathway 24 also includes at least one layer of transparent film 26, and at least one layer of reflective film 28. In an embodiment, the layer of reflective film 28 includes an aperture 30 to interface with an external optical path, such as an up level micro controller circuit, which also has an optical communication device 16, such that data about the batteries 10,10a may be communicated outside of the optical pathway 24.

The battery 10a also includes a housing 12a, and the layer of transparent film 26 is attached to a first outer surface 32,32a of each housing 12,12a, such that the layer of transparent film 26 covers the openings 14,14a of each housing 12,12a. The layer of reflective film 28 is attached to the layer of transparent film 26, as shown in FIG. 3. During operation, the optical emitter 20 emits a first optical signal which is directed towards the layer of transparent film 26, where the first optical signal then travels through the layer of transparent film 26, and is reflected off of the inner surface of the layer of reflective film 28. The first optical signal is then detected by the optical sensor 22a of the optical communication device 16a. Similarly, the optical emitter 20a may emit a second optical signal which is also directed towards the layer of transparent film 26, where the second optical signal then travels through the layer of transparent film 26 and is reflected off of the inner surface of the layer of reflective film 28. The second optical signal is then detected by the optical sensor 22 of the optical communication device 16. As a result, information may be passed between the two optical communication devices 16,16a of the BMS. In this embodiment, the first optical signal and the second optical signal do not need to be the same wavelength. In this embodiment, there is no need for different types of optical signals having different wavelengths because there is only two optical communication devices 16,16a which communicate with each other. During operation, the optical emitters 20,20a do not emit optical signals simultaneously, but rather when the optical emitter 20 emits the first optical signal, the optical emitter 20a is inactive, and when the optical emitter 20a emits the second optical signal, the optical emitter 20 is inactive.

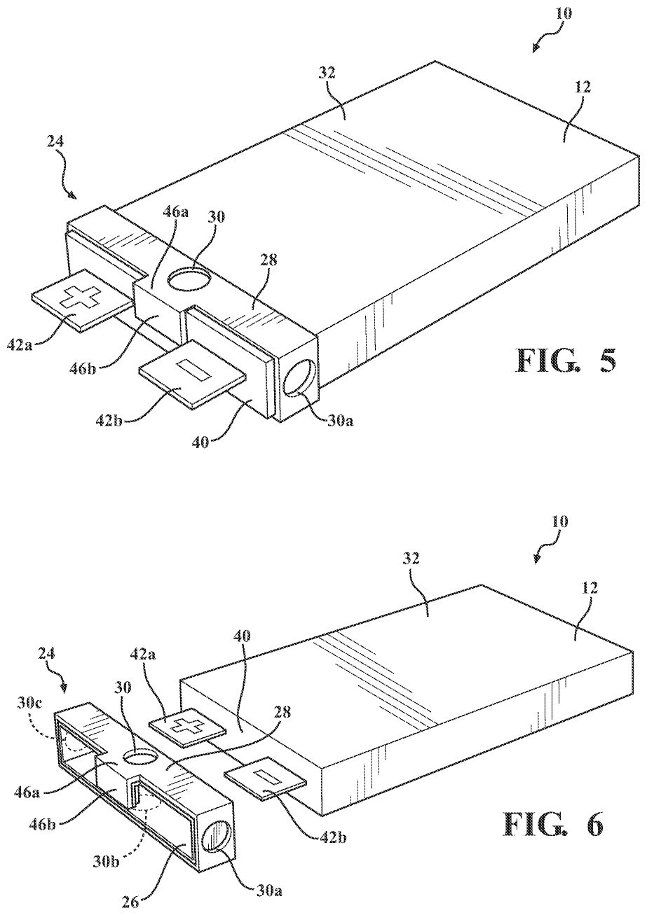

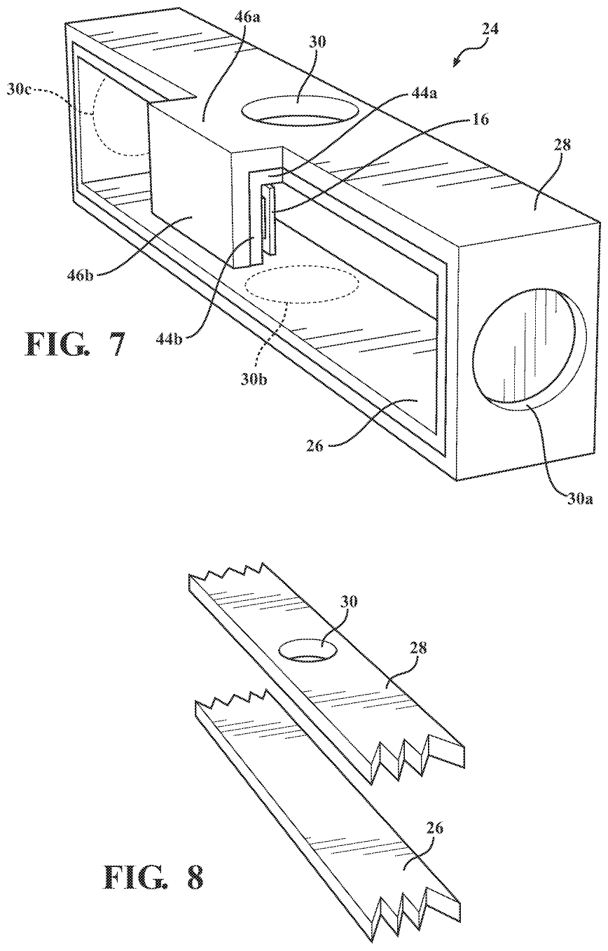

Another embodiment of the invention is shown in FIGS. 5-8, with like numbers referring to like elements. In this embodiment, the layer of transparent film 26 and the layer of reflective film 28 of the first optical pathway 24 circumscribe the battery 10, as shown in FIGS. 5 and 6, such that the layer of transparent film 26 and the layer of reflective film 28 are in a substantially rectangular shape, which corresponds to the shape of the housing 12. In this embodiment, there is a plurality of apertures 30,30a,30b,30c integrally formed as part of the layer of reflective film 28.

In this embodiment, the optical communication device 16 is mounted to a side surface 40 of the battery 10, such that the optical communication device 16 is located between the positive terminal 42a and the negative terminal 42b. The layer of transparent film 26 has a first protrusion 44a and a second protrusion 44b, which is substantially perpendicular to the first protrusion 44a, where the protrusions 44a,44b are made of the same material as the remaining parts of the layer of transparent film 26. The layer of reflective film 28 also has a first protrusion 46a and a second protrusion 46b, which is substantially perpendicular to the first protrusion 46a, where the protrusions 46a,46b are made of the same material as the remaining parts of the layer of reflective film 28. The protrusions 44a,46a are in contact with one another in a similar manner the remaining parts of the layer of transparent film 26 and the layer of reflective film 28. Similarly, the protrusions 44b,46b are in contact with one another in a similar manner the remaining parts of the layer of transparent film 26 and the layer of reflective film 28.

During operation, the optical emitter 20 of the optical communication device 16 emits an optical signal which travels through the layer of transparent film 26 which forms the protrusions 44a,44b, and through other parts of the layer of transparent film 26, such that the optical signal may be emitted through the apertures 30,30a,30b,30c. This allows the optical communication device 16 to communicate with the corresponding optical communication device of any adjacent batteries.

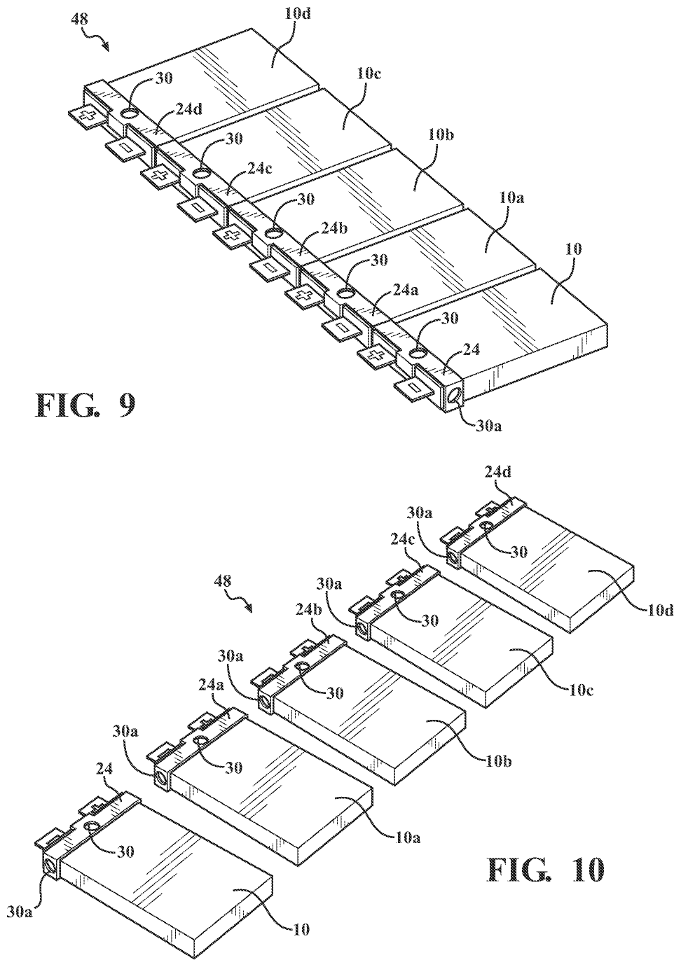

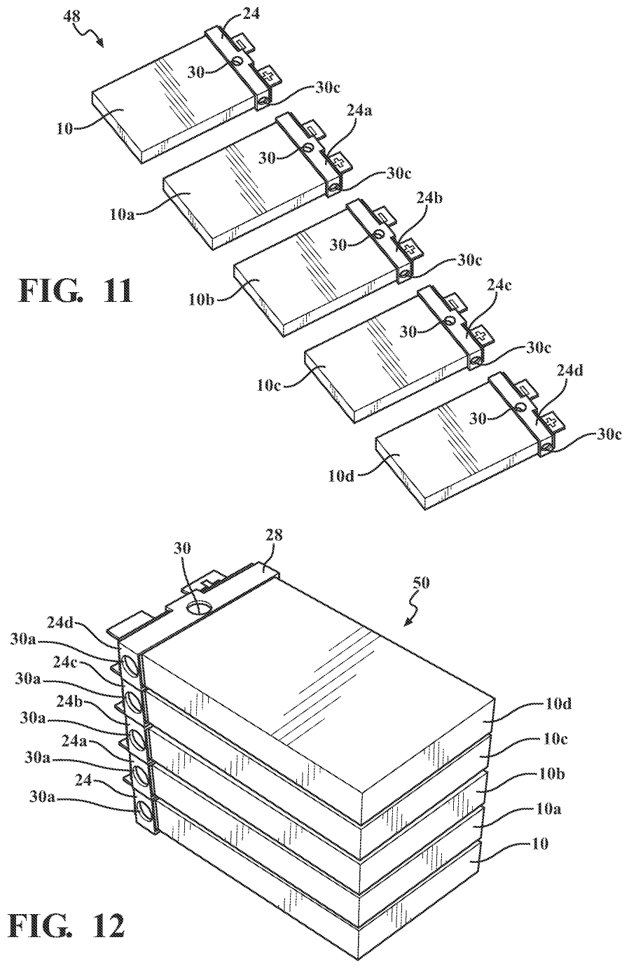

An example of a BMS according to the present invention which facilitates communication between adjacent batteries is shown in FIGS. 9-11, with like numbers referring to like elements. In the example shown, there are five batteries 10,10a, 10b,10c,10d which are adjacent one another horizontally to form a horizontal battery pack, shown generally at 48. Each additional battery 10a, 10b, 10c, 10d is similar to the battery 10 described in FIGS. 5-8, and each additional battery 10a, 10b, 10c, 10d includes an optical pathway 24a,24b,24c,24d, and each an optical pathway 24a,24b,24c,24d includes an optical communication device 16 as described above. During operation, the optical emitter 20 of the optical pathway 24 emits a first optical signal which may pass through the aperture 30c of the optical pathway 24, where the first optical signal then passes through the aperture 30a of the optical pathway 24a connected to the battery 10a and is then received by the optical sensor 22a of the optical pathway 24a. Similar communication is achieved between the batteries 10a, 10b, 10c, 10d using the optical pathways 24a,24b,24c,24d.

All of the batteries 10,10a, 10b, 10c, 10d shown in FIGS. 9-11 are able to communicate with each other in a similar manner. Any optical emitter of any of the optical pathways 24,24a,24b,24c,24d may emit an optical signal which is received by one or more of the optical sensors of the optical pathways 24,24a,24b,24c,24d, and each corresponding controlling circuit may process the optical signal and respond accordingly. As with the previous embodiment, the optical emitters of the optical pathways 24,24a,24b,24c,24d do not emit optical signals simultaneously, but rather one optical signal is emitted at a time. In a non-limiting example, the optical emitter of the optical pathway 24b emits an optical signal which may pass through both of the apertures 30a,30c of the optical pathway 24b, where the optical signal then passes through the aperture 30a of the optical pathway 24c connected to the battery 10c and is then received by the optical sensor of the optical pathway 24c, and the optical signal may also pass through the aperture 30c of the optical pathway 24a connected to the battery 10a and is then received by the optical sensor of the optical pathway 24a. Additionally, after passing through the optical pathway 24c of the fourth battery 10c, the optical signal may pass through the aperture 30c of the optical pathway 24c and through the aperture 30a of the optical pathway 24d of the fifth battery 10d and is then received by the optical sensor of the optical pathway 24d.

Additionally, in the embodiment shown in FIGS. 9-11, the optical emitter 20 of the optical pathway 24 (of the first battery 10) may emit a signal that is transmitted through the aperture 30a of the optical pathway 24 to an optical communication device outside of the battery pack 48. Also, the optical emitter 20 of the optical pathway 24d (of the fifth battery 10d) may emit an optical signal that is transmitted through the aperture 30c of the fifth battery 10d to an optical communication device outside of the battery pack 48.

In a non-limiting example, in a BMS according to the present invention having multiple optical communication devices, one of the optical communication devices functions as a primary optical communication device having a primary optical emitter and a primary optical sensor, and the remaining optical communication devices function as secondary optical communication devices having secondary optical emitters and secondary optical sensors. The primary optical emitter emits a first spectrum optical signal which is received by the secondary optical sensors, and the secondary optical emitters emit a second spectrum optical signal which is received by the primary optical sensor. In the embodiment shown in FIGS. 9-11, the first optical communication device 16 of the first optical pathway 24 is the primary optical communication device, and the optical communication devices of the other optical pathways 24a,24b,24c,24d are the secondary optical communication devices.

Another embodiment of the present invention is shown in FIG. 12, with like numbers referring to like elements. In this embodiment, there are five batteries 10,10a, 10b, 10c, 10d, where each additional battery 10a, 10b, 10c, 10d is similar to the battery 10 described in FIGS. 5-8, and each additional battery 10,10a, 10b, 10c, 10d includes an optical pathway 24a,24b,24c,24d, and each an optical pathway 24a,24b,24c,24d includes an optical communication device 16. In this embodiment, the batteries 10,10a, 10b, 10c, 10d are stacked one on top of the other, in a vertical configuration to form a vertical battery pack, shown generally at 50. During operation, the optical emitter 20 of each optical communication device 16 emits an optical signal which may pass through one or both of the apertures 30,30b, and be transmitted to the optical communication device 16 of the adjacent battery 10,10a, 10b, 10c, 10d.

Additionally, in the embodiment shown in FIG. 12, the optical emitter 20 of the optical pathway 24 (of the first battery 10) may emit a signal that is transmitted through aperture 30b of the optical pathway 24 to an optical communication device outside of the battery pack 50. Also, the optical emitter 20 of the optical pathway 24d (of the fifth battery 10d) may emit an optical signal that is transmitted through the aperture 30 of the fifth battery 10d to an optical communication device outside of the battery pack 50.

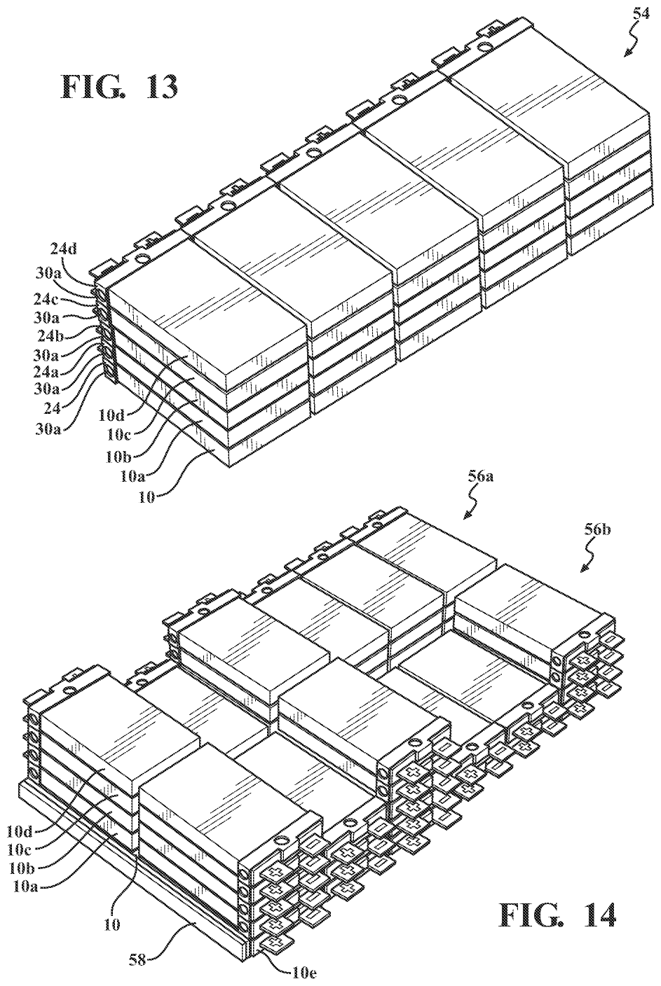

Another embodiment of the present invention is shown in FIG. 13, with like numbers referring to like elements. In this embodiment, a battery pack, shown generally at 54, is created using several horizontal battery packs 48 and/or vertical battery packs 50, such that twenty-five batteries are used. Any one of the optical emitters 20 of the optical communication devices 16 of the batteries which are on the outer periphery of the battery pack 54 may emit an optical signal that is transmitted to an optical communication device outside of the battery pack 54. Also, each of the optical emitters 20 of the optical communication devices 16 of each optical pathway 24 of the battery pack 54 may communicate with each other in the manner previously described.

Another embodiment of the present invention is shown in FIGS. 14-15, with like numbers referring to like elements. In this embodiment, several batteries are used and configured in an irregular shape to form a first irregularly shaped battery pack, shown generally at 56a. Additional batteries are used and configured in another irregular shape to form a second irregularly shaped battery pack, shown generally at 56b, where the shape of the second irregularly shaped battery pack 56b is different from the shape of the first irregularly shaped battery pack 56a. Each battery in the first irregularly shaped battery pack 56a includes an optical pathway 24, such that the various batteries of the first irregularly shaped battery pack 56a are able to communicate with one another. Similarly, each battery in the second irregularly shaped battery pack 56b includes an optical pathway 24, such that the various batteries of the second irregularly shaped battery pack 56b are able to communicate with one another. In the embodiment shown in FIGS. 14-15, there is also an extended optical pathway 58 which is connected to a side surface of a battery in the first irregularly shaped battery pack 56a and is also connected to a side surface of a battery in the second irregularly shaped battery pack 56b. Although the irregularly shaped battery packs 56a,56b are configured as shown in FIG. 14, it is within the scope of the invention that either or both of the irregularly shaped battery packs 56a,56b may be configured such that the batteries are stacked differently to accommodate various packaging requirements of any application. A greater or lesser number of batteries may be used as well.

Referring to FIG. 15, the extended optical pathway 58 also includes a layer of transparent film 60a and a layer of reflective film 60b. An optical signal emitted from the optical communication device 16 of the battery 10 of the first irregularly shaped battery pack 56a may be transmitted through the aperture 30a, through the extended optical pathway 58, and through the aperture 30c and to the optical communication device 16 of the battery 10e of the second irregularly shaped battery pack 56b, and vice versa. This facilitates communication between the irregularly shaped battery packs 56a,56b.

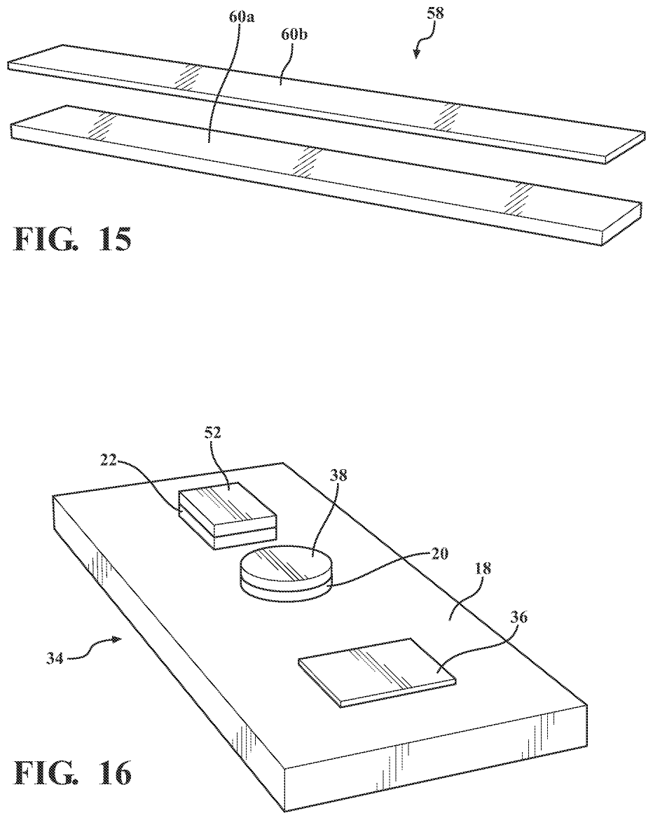

An alternate embodiment of the optical communication device is shown in FIG. 16, generally at 34, with like numbers referring to like elements. Referring to FIG. 16, in this alternate embodiment, the optical communication device 34 also includes a first band pass filter 38 mounted to the optical emitter 20, and a second band pass filter 52 mounted to optical sensor 22. The band pass filter 38 restricts the optical signal emitted from the optical emitter 20 in FIG. 16 to a specific spectrum optical signal, and the band pass filter 52 restricts the optical signal received by the optical sensor 22 to a specific spectrum optical signal. Other optical communication devices may have band pass filters which restrict the optical signal emitted from a corresponding optical emitter to a different specific spectrum optical signal, and/or band pass filters which restrict the optical signal received by a corresponding optical sensor to a different specific spectrum optical signal. Each optical emitter and optical sensor and band pass filters generating/receiving a different spectrum optical signal allows for each of the spectrum optical signals to be transmitted simultaneously without interfering with one another.

The description of the invention is merely exemplary in nature and, thus, variations that do not depart from the gist of the invention are intended to be within the scope of the invention. Such variations are not to be regarded as a departure from the spirit and scope of the invention.

What is claimed is:

1. An apparatus, comprising:
a battery management system, comprising:
at least one optical pathway, further comprising:
at least one optical communication device connected to one of a plurality of batteries;
wherein the at least one optical communication device emits one or more optical signals, the one or more optical signals including data about at least one of the plurality of batteries.

2. The apparatus of claim 1, the at least one optical communication device further comprising a plurality of optical communication devices, each of the plurality of optical communication devices connected to a corresponding one of the plurality of batteries.

3. The apparatus of claim 2, each of the plurality of optical communication devices further comprising:
an optical emitter operable for emitting the one or more optical signals;
an optical sensor operable for receiving the one or more optical signals; and
a printed circuit board (PCB);
wherein the optical emitter and the optical sensor are mounted to the PCB.

4. The apparatus of claim 3, the at least one optical pathway further comprising:
at least one layer of transparent film, a first portion of the at least one layer of transparent film is mounted to an external surface of a first of the plurality of batteries, and a second portion of the at least one layer of transparent film is mounted to an external surface of a second of the plurality of batteries; and
at least one layer of reflective film connected to the at least one layer of transparent film;
wherein the optical emitter of each of the plurality of optical communication devices emits the one or more optical signals which pass through the at least one layer of transparent film and reflects off of the at least one layer of reflective film, such that the one or more optical signals emitted by the optical emitter of each of the plurality of optical communication devices is received by the optical sensor of one of the plurality of optical communication devices.

5. The apparatus of claim 4, the at least one optical pathway further comprising:
at least one aperture integrally formed as part of the at least one layer of reflective film;
wherein the one or more optical signals pass through the at least one aperture, such that the one or more optical signals are transmitted to a second optical communication device.

6. The apparatus of claim 1, the at least one optical pathway further comprising a plurality of optical pathways, and the at least one optical communication device further comprising a plurality of optical communication devices, each of the plurality of optical communication devices being part of a corresponding one of the plurality of optical pathways, each of the plurality of optical pathways connected to and circumscribing a corresponding one of the plurality of batteries.

7. The apparatus of claim 6, each of the plurality of optical pathways further comprising:
a layer of transparent film circumscribing one of the plurality of batteries; and
a layer of reflective film connected to the layer of transparent film;
wherein the at least one optical communication device emits the one or more optical signals and receives another of the one or more optical signals.

8. The apparatus of claim 7, each of the optical communication devices further comprising:
an optical emitter operable for emitting the one or more optical signals, such that the one or more optical signals passes through the layer of transparent film;
an optical sensor operable for receiving the one or more optical signals; and
a printed circuit board (PCB);
wherein the optical emitter and the optical sensor are mounted to the PCB.

9. The apparatus of claim 8, each of the optical communication devices further comprising:
a first band pass filter mounted to the optical emitter; and
a second band pass filter mounted to the optical sensor;
wherein the first band pass filter restricts the one or more optical signals emitted from the optical emitter and the second band pass filter restricts the one or more optical signals received by the optical sensor to a specific spectrum optical signal.

10. The apparatus of claim 7, further comprising:
at least one aperture integrally formed as part of the layer of reflective film;
wherein the specific spectrum optical signal passes through the at least one aperture of a first of the plurality of optical pathways and is transferred to a second of the plurality of optical pathways.

11. The apparatus of claim 6, the plurality of batteries further comprising one of a horizontal battery pack or a vertical battery pack.

12. The apparatus of claim 6, the plurality of batteries further comprising:
a first irregular battery pack;
a second irregular battery pack; and
an extended optical pathway which provides communication between the first irregular battery pack and the second irregular battery pack.

13. The apparatus of claim 12, the extended optical pathway further comprising:
a layer of transparent film; and
a layer of reflective film connected to the layer of transparent film;
wherein a first portion of the layer of transparent film is mounted to an external surface of a battery which is part of the first irregular battery pack, and an external surface of a battery which is part of the second irregular battery pack.

14. A battery management system, comprising:
at least one optical pathway, further comprising:
at least one layer of transparent film, at least a portion of the at least one layer of transparent film is mounted to an external surface of a first of a plurality of batteries;
at least one layer of reflective film connected to the at least one layer of transparent film;
at least one optical communication device connected to one of a plurality of batteries, the at least one optical communication device further comprising:
an optical emitter operable for emitting at least one optical signal;
an optical sensor operable for receiving the at least one optical signal; and
a printed circuit board (PCB), the optical emitter and the optical sensor are mounted to the PCB;
wherein the at least one optical communication device emits at least one optical signal, the at least one optical signal including data about the one of the plurality of batteries.

15. The battery management system of claim 14, the at least one optical communication device further comprising a plurality of optical communication devices.

16. The battery management system of claim 15, further comprising:
each of the plurality of optical communication devices connected to a corresponding one of the plurality of batteries
a first portion of the at least one layer of transparent film mounted to an external surface of a first of the plurality of batteries, and
a second portion of the at least one layer of transparent film mounted to an external surface of a second of the plurality of batteries; and
wherein the optical emitter of each of the plurality of optical communication devices emits the one or more optical signals which pass through the at least one layer of transparent film and reflects off of the at least one layer of reflective film, such that the one or more optical signals emitted by the optical emitter of each of the plurality of optical communication devices is received by the optical sensor of one of the plurality of optical communication devices.

17. The battery management system of claim 15, the at least one optical pathway further comprising:
at least one aperture integrally formed as part of the at least one layer of reflective film;
wherein the at least one optical signal passes through the at least one aperture, such that the at least one optical signal is transmitted to an optical communication device outside of the at least one optical pathway.

18. The battery management system of claim 14, the at least one optical pathway further comprising a plurality of optical pathways and the at least one optical communication device further comprising a plurality of optical communication devices such that each of the plurality of optical communication devices is part of a corresponding one of the plurality of optical pathways, each of the plurality of optical pathways connected to a corresponding one of the plurality of batteries.

19. The battery management system of claim 18, each of the plurality of optical communication devices further comprising:
a first band pass filter mounted to the optical emitter;
a second band pass filter mounted to the optical sensor;
wherein the first band pass filter restricts the one or more optical signals emitted from the optical emitter and the one or more optical signals received by the optical sensor to a specific spectrum optical signal.

20. The battery management system of claim 18, the plurality of batteries further comprising one of a horizontal battery pack or a vertical battery pack.

21. The battery management system of claim 18, the plurality of batteries further comprising:
a first irregular battery pack;
a second irregular battery pack; and
an extended optical pathway which provides communication between the first irregular battery pack and the second irregular battery pack.

22. The battery management system of claim 21, the extended optical pathway further comprising:
a layer of transparent film; and
a layer of reflective film connected to the layer of transparent film;
wherein a first portion of the layer of transparent film is mounted to an external surface of a battery which is part of the first irregular battery pack, and a second portion of the layer of transparent film is mounted to an external surface of a battery which is part of the second irregular battery pack.
